(19) United States
(12) Patent Application Publication
(10) Pub. No.: US 2026/0253659 A1
(43) Pub. Date: Aug. 27, 2026

(54) SEMICONDUCTOR MEMORY DEVICES AND MEMORY SYSTEMS INCLUDING THE SAME

(71) Applicant: SAMSUNG ELECRONICS CO., LTD, Suwon-si (KR)

(72) Inventors: Donggeun LEE, Suwon-si (KR); Sungrae KIM, Suwon-si (KR); Kiwon LEE, Suwon-si (KR)

(73) Assignee: SAMSUNG ELECRONICS CO., LTD, Suwon-si (KR)

(21) Appl. No.: 19/381,752

(22) Filed: Nov. 6, 2025

(30) Foreign Application Priority Data
Feb. 25, 2025 (KR) 10-2025-0024215

(51) Int. Cl. G11C 29/42; G11C 29/14; G11C 29/36

(52) U.S. Cl. CPC G11C 29/42; G11C 29/14; G11C 29/36; G11C 2029/3602

(57) ABSTRACT

A semiconductor memory device includes a memory cell array, an on-die error correction code (ECC) engine, a link ECC engine, a latch circuit and a control logic circuit. The control logic circuit, in response to a first mode register set command, sets the on-die ECC engine and the link ECC engine to a test mode and cuts off connection between the on-die ECC engine and the memory cell array by disabling the on-die ECC engine. The link ECC engine, in the test mode, receives a write command, a first link parity data and a first test data that selectively includes at least one error bit, generates a second test data by performing an ECC decoding operation on the first test data based on the first link parity data and by correcting an error bit of the first test data and stores the second test data in the latch circuit.

### CROSS-REFERENCE TO RELATED APPLICATION

This application claims priority to Korean Patent Application No. 10-2025-0024215, filed on Feb. 25, 2025, in the Korean Intellectual Property Office (KIPO), the disclosure of which is incorporated herein by reference in its entirety.

### BACKGROUND

The present disclosure relates to memories, and more particularly to semiconductor memory devices and memory systems including the same.

High speed operation and cost efficiency of a volatile memory device such as a dynamic random access memory (DRAM) make it possible for DRAMs to be used for system memories. Due to the continuing shrink in fabrication design rule of DRAMs, bit errors of memory cells in the DRAMs may rapidly increase and yield of the DRAMs may decrease.

### SUMMARY

One or more example embodiments provide a semiconductor memory device capable of enhancing test coverage.

One or more example embodiments provide a memory system capable of enhancing test coverage.

According to example embodiments, a semiconductor memory device includes: a memory cell array including a plurality of memory cells coupled to a plurality of word-lines and a plurality of bit-lines; an on-die error correction code (ECC) engine; a link ECC engine;

a latch circuit; and a control logic circuit configured to control the on-die ECC engine and the link ECC engine. The control logic circuit is further configured to, in response to a first mode register set command from an external device, set the on-die ECC engine and the link ECC engine to a test mode, and cut off connection between the on-die ECC engine and the memory cell array by disabling the on-die ECC engine. The link ECC engine is configured to, in the test mode: receive a write command, a first link parity data and a first test data that selectively includes at least one error bit from the external device; generate a second test data by performing an ECC decoding operation on the first test data based on the first link parity data and by correcting an error bit of the first test data; and store the second test data in the latch circuit.

According to example embodiments, a memory system includes: a semiconductor memory device; and a memory controller configured to control the semiconductor memory device. The semiconductor memory device includes: a memory cell array including a plurality of memory cells coupled to a plurality of word-lines and a plurality of bit-lines; an on-die ECC engine; a link ECC engine; a latch circuit disposed at an outside of the on-die ECC engine and the link ECC engine; and a control logic circuit configured to control the on-die ECC engine and the link ECC engine. The control logic circuit is further configured to, in response to a first mode register set command from the memory controller, set the on-die ECC engine and the link ECC engine to a test mode, and cut off a connection between the on-die ECC engine and the memory cell array by disabling the on-die ECC engine. The link ECC engine is configured to, in the test mode: receive a write command, a first link parity data and a first test data that selectively includes at least one error bit from the memory controller; generate a second test data by performing an ECC decoding operation on the first test data based on the first link parity data and by correcting an error bit of the first test data; store the second test data in the latch circuit; generate a second link parity data by performing an ECC encoding operation on the second test data stored in the latch circuit in response to a read command from the memory controller; and transmit the second test data and the second link parity data to the memory controller.

According to example embodiments, a semiconductor memory device includes: a memory cell array including a plurality of memory cells coupled to a plurality of word-lines and a plurality of bit-lines; an on-die ECC engine; a link ECC engine; a latch circuit disposed at an outside of the on-die ECC engine and the link ECC engine; and a control logic circuit configured to control the on-die ECC engine and the link ECC engine. The control logic circuit is further configured to, in response to a mode register set command from an external device, set the on-die ECC engine and the link ECC engine to a test mode, and cut off a connection between the on-die ECC engine and the memory cell array by disabling the on-die ECC engine. The link ECC engine, in the test mode, is configured to: generate a link parity data by performing an ECC encoding operation on a test data stored in the latch circuit based on a read command from the external device; and transmit the test data and the link parity data to the external device.

According to example embodiments, there is provided a method of operating a memory system including a semiconductor memory device and a memory controller to control the semiconductor memory device. The semiconductor memory device includes a memory cell array, an on-die ECC engine, a link ECC engine, a latch and a control logic circuit. According to the method, a mode register set command is transmitted, by the memory controller, to the semiconductor memory device, the semiconductor memory device is set, by the control logic circuit, to a test mode associated with testing the link ECC engine, the on-die ECC engine is disabled by the control logic circuit, a first link parity data and a first test data that selectively includes at least one error bit is transmitted, by the memory controller, to the semiconductor memory device, a second data is generated by the link ECC engine performing an ECC decoding on the first test data, and the second test data is stored in the latch. A read command is transmitted, by the memory controller, to the semiconductor memory device, a second link parity data is generated, in response to the read command, by the link ECC engine performing an ECC encoding on the second test data stored in the latch, the second test data and the second link parity data are transmitted to the memory controller, and it is determined by the memory controller based on the second test data and the second link parity data whether the link ECC engine operates normally.

Accordingly, according to example embodiments, in the semiconductor memory device, the control logic circuit in the test mode, may cut off a connection between the on-die ECC engine and the memory cell array, and the link ECC engine may generate a second test data by performing an ECC decoding on a first parity data that selectively include an error bit based on a first link parity data, may store the second test data in the latch, may generate a second link parity data by performing an ECC encoding on the second test data and may transmit the second test data and the second link parity data to the memory controller. The memory controller may determine whether the link ECC engine operates normally based on the second test data and the second link parity dat. Therefore, the semiconductor memory device may test the link ECC engine with respect to various error patterns with blocking influence from the on-die ECC engine and the memory cell array and thus may enhance test coverage.

### BRIEF DESCRIPTION OF DRAWINGS

Example embodiments will be described below in more detail with reference to the accompanying drawings.

FIG. 1 is a block diagram illustrating a memory system according to example embodiments.

FIG. 2 is a block diagram illustrating an example of the memory controller in the memory system of FIG. 1 according to example embodiments.

FIG. 3 illustrates a data set corresponding to a plurality of burst lengths in the memory system of FIG. 1 according to example embodiments.

FIG. 4 illustrates the error injection register set, the data buffer and the test data generator in the memory controller of FIG. 2 according to example embodiments.

FIG. 5 illustrates second data bits that may be stored in the error injection register set in FIG. 4.

FIGS. 6 and 7 illustrate various error patterns that the error injection register set may represent according to example embodiments.

FIG. 8 is a block diagram illustrating an example of the semiconductor memory device in the memory system of FIG. 1 according to example embodiments.

FIG. 9 illustrates an example of the first bank array in the semiconductor memory device of FIG. 8 according to example embodiments.

FIG. 10 illustrates a portion of the semiconductor memory device of FIG. 8.

FIG. 11 illustrates the semiconductor memory device of FIG. 10 in the test mode.

FIG. 12 illustrates the semiconductor memory device of FIG. 10 in the normal mode.

FIG. 13 illustrates an example of the encoding/decoding logic in the on-die ECC engine of FIG. 10 according to example embodiments.

FIG. 14 illustrates an example of the data corrector in the on-die ECC engine of FIG. 10 according to example embodiments.

FIG. 15 illustrates a command sequence that the semiconductor memory device receives in the test mode according to example embodiments.

FIG. 16 illustrates data input to/output from the link ECC engine of FIG. 10 in the test mode according to example embodiments.

FIG. 17 illustrates data input to/output from the link ECC engine of FIG. 10 in the test mode according to example embodiments.

FIGS. 18A and 18B illustrate an example operation of the memory system of FIG. 1 according to example embodiments.

FIG. 19 illustrates a portion of the semiconductor memory device of FIG. 8 for explaining a test mode.

FIG. 20 illustrates a portion of the semiconductor memory device of FIG. 8 for explaining a normal mode.

FIG. 21 is a flow chart illustrating a method of operating a semiconductor memory device according to example embodiments.

FIG. 22 is a flow chart illustrating a method of operating a memory system according to example embodiments.

FIG. 23 is a block diagram illustrating a semiconductor memory device according to example embodiments.

FIG. 24 is a diagram illustrating a semiconductor package including the stacked memory device, according to example embodiments.

### DETAILED DESCRIPTION

Various example embodiments will be described more fully hereinafter with reference to the accompanying drawings, in which example embodiments are shown. Each example embodiment provided in the following description is not excluded from being associated with one or more features of another example or another example embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. It will be also understood that, even if a certain step or operation of manufacturing an apparatus or structure is described later than another step or operation, the step or operation may be performed later than the other step or operation unless the other step or operation is described as being performed after the step or operation.

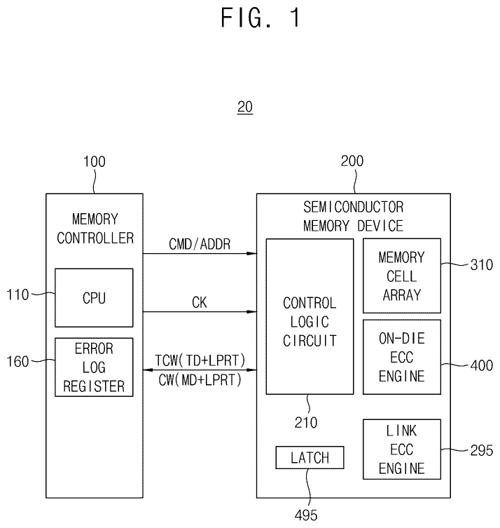

FIG. 1 is a block diagram illustrating a memory system according to example embodiments.

Referring to FIG. 1, a memory system 20 may include a memory controller 100 and a semiconductor memory device 200.

The memory controller 100 may control overall operation of the memory system 20. The memory controller 100 may control overall data exchange between an external host and the semiconductor memory device 200. For example, the memory controller 100 may write data in the semiconductor memory device 200 or read data from the semiconductor memory device 200 in response to a request from the host. The memory controller 100 may be referred to as an external device.

In addition, the memory controller 100 may issue operation commands to the semiconductor memory device 200 for controlling the semiconductor memory device 200. The memory controller 100 may be referred to as an external device.

In some example embodiments, the semiconductor memory device 200 is a memory device including dynamic memory cells such as a dynamic random access memory (DRAM), or a low power (LP) double data rate 6 (DDR6) synchronous DRAM (SDRAM).

The memory controller 100 may transmit a command CMD and an address signal ADDR to the semiconductor memory device 200, may transmit a clock signal CK to the semiconductor memory device 200, may transmit a codeword CW including a main data MD and a link parity data LPRT to the semiconductor memory device 200 in a normal mode, may receive the codeword CW from the semiconductor memory device 200 in the normal node, may transmit a test codeword TCW including a test data TD and a link parity data LPRT to the semiconductor memory device 200 in a test mode and may receive the test codeword TCW from the semiconductor memory device 200 in the test mode.

The memory controller 100 may include a central processing unit (CPU) 110 and an error log register 160. The CPU 110 may control overall operation of the memory controller 100.

The semiconductor memory device 200 may include a memory cell array 310 that stores the main data MD, an on-die error correction code (ECC) engine 400, a link ECC engine 295, a latch (i.e., latch circuit) 495 and a control logic circuit 210.

The control logic circuit 210 may control access to the memory cell array 310 and may control the on-die ECC engine 400 and the link ECC engine 295 based on the command CMD and the address ADDR. The control logic circuit 210 may set the semiconductor memory device 200 to a test mode based on a first mode register set command from the memory controller (e.g., an external device) 100. That is, the control logic circuit 210 may set the on-die ECC engine 400 and the link ECC engine 295 to the test mode in response to the first mode register set command and may cut off a connection between the on-die ECC engine 400 and the memory cell array 310 by disabling the on-die ECC engine 400.

The link ECC engine 295, in the test mode, may receive a first link parity data and a first test data selectively including at least one error bit, which are accompanied by a write command from the memory controller 100, may generate a second test data by performing an ECC decoding operation on the first test data based on the first link parity data and by correcting an error bit of the first test data, may store the second test data in the latch 495, may generate a second link parity data by performing an ECC encoding operation on the second test data stored in the latch 495 in response to a read command from the memory controller 100 and may transmit the second test data and the second link parity data to the memory controller 100.

The memory controller 100 (or the CPU 110) may determine whether the link ECC engine 295 operates normally by comparing each of the second test data and the second link parity data with respective one of an expected test data and an expected link parity data, and may store, in the error log register 160, test information of the link ECC engine 295, which is associated with various error patterns of the test data TD and the link parity data LPRT.

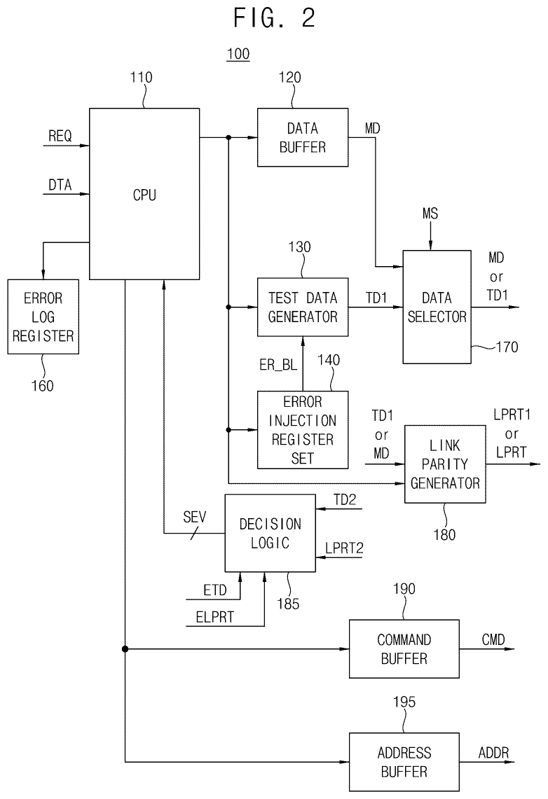

FIG. 2 is a block diagram illustrating an example of the memory controller in the memory system of FIG. 1 according to example embodiments.

Referring to FIG. 2, the memory controller 100 may include the CPU 110, a data buffer 120, a test data generator 130, an error injection register set 140, a data selector 170, the error log register 160, a link parity generator 180, a decision logic 185, a command buffer 190 and an address buffer 195.

The CPU 110 may receive a request REQ and a data DTA from the host, and may provide the data DTA to the data buffer 120. The CPU 110 may control the data buffer 120, the test data generator 130, the error injection register set 140, the data selector 170, the error log register 160, the link parity generator 180, the command buffer 190 and the address buffer 195.

The CPU 110 may determine, in the test mode, whether the link ECC engine 295 operates normally based on a severity signal SEV from the decision logic 185.

The data buffer 120 may buffer the data DTA to provide the main data MD to the data selector 170. The error injection register set 140 may store an error bit set including at least one error bit, and the error bit set may be associated with the test data TD to be provided to the semiconductor memory device 200.

The test data generator 130, in the test mode, may generate a first test data TD1 based on an error bit set ER_BL and may provide the first test data TDI to the data selector 170 under control of the CPU 110. The data selector 170, based on a mode signal MS from the CPU 110, may select the main data MD to provide the main data MD to the semiconductor memory device 200 in the normal mode and may select the first test data TD1 to provide the first test data TDI to the semiconductor memory device 200 in the test mode.

The link parity generator 180 may generate a first link parity data LPRT1 based on the first test data TD1 to provide the first link parity data LPRT1 to the semiconductor memory device 200 in the test mode and may generate a link parity data LPRT based on the main data MD to provide the link parity data LPRT to the semiconductor memory device 200 in the normal mode.

The decision logic 185, in the test mode, may receive a second test data TD2 and a second link parity data LPRT2 from the semiconductor memory device 200, may generate a severity signal SEV by comparing each of the second test data TD2 and the second link parity data LPRT2 with respective one of an expected test data ETD and an expected link parity data ELPRT and may provide the severity signal SEV to the CPU 110. The CPU 110 may determine whether the link ECC engine 295 operates normally based on the severity signal SEV and may store, in the error log register 160, test information of the link ECC engine 295, which is associated with various error patterns of the first test data TDI and the first link parity data LPRT1.

The command buffer 190 may store the command CMD corresponding to the request REQ and may transmit the command CMD to the semiconductor memory device 200 under control of the CPU 110. The address buffer 195 may store the address ADDR and may transmit the address ADDR to the semiconductor memory device 200 under control of the CPU 110.

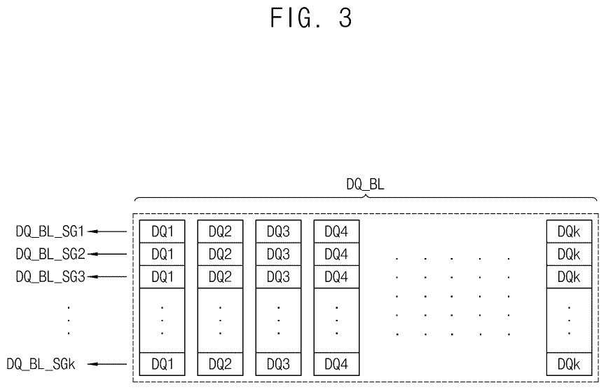

FIG. 3 illustrates a data set corresponding to a plurality of burst lengths in the memory system of FIG. 1 according to example embodiments.

Referring to FIG. 3, a data set DQ_BL corresponding to a plurality of burst lengths are input to/output from the semiconductor memory device 200. The data set DQ_BL includes data segments DQ_BL_SG1, DQ_BL_SG2, DQ_BL_SG3, . . . , DQ_BL_SGk, each of the data segments corresponding to each of the plurality of burst lengths, where k is an integer greater than three. The data set DQ_BL corresponding to the plurality of burst lengths may be stored in the memory cell array 300 of the semiconductor memory device 200. The data set DQ_BL may include the main data MD and the test data TD.

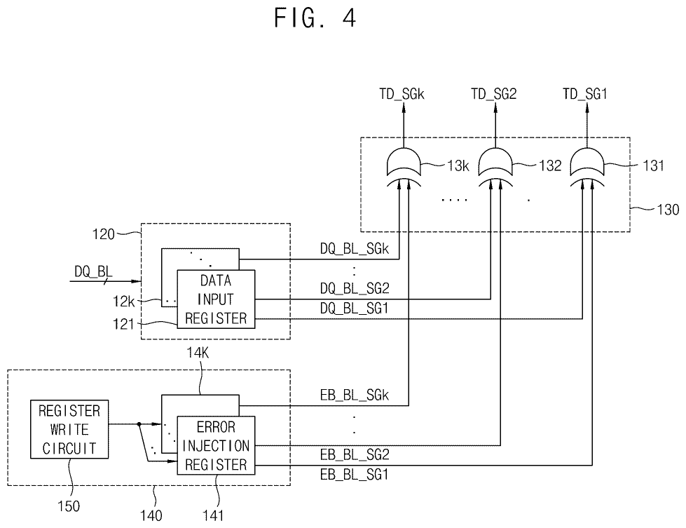

FIG. 4 illustrates the error injection register set, the data buffer and the test data generator in the memory controller of FIG. 2 according to example embodiments.

Referring to FIG. 4, the error injection register set 140 may include a register write circuit 150 and a plurality of error injection registers 141~14k. The data buffer 120 may include a plurality of data input registers 121~12k. Each of the data input registers 121~12k may store corresponding one of first units of first data bits DQ_BL_SG1~DQ_BL_SGk, corresponding to a burst length of the semiconductor memory device 200, in the data set DQ_BL. Each of the data input registers 121~12k may provide the test data generator 130 with corresponding one of first units of first data bits DQ_BL_SG1~DQ_BL_SGk in the data set DQ_BL.

Each of the error injection registers 141~14k may store corresponding one of second units of second data bits EB_BL_SG1~EB_BL_SGk corresponding to each of the data input registers 121~12k and to each of the first units of first data bits DQ_BL_SG1~DQ_BL_SGk. A size of the first unit may be the same as a size of the second unit.

The register write circuit 150 may maintain the second data bits stored in the error injection registers 141~14k at a default level (a first logic level, i.e., a logic low level) or may change at least one of the second data bits to a second logic level based on a control of the CPU 110.

The test data generator 130 may include a plurality of exclusive OR gates 131, 132, . . . , 13k.

The plurality of exclusive OR gates 131, 132, . . . , 13k may perform an exclusive OR operation on corresponding data bits of the first units of first data bits DQ_BL_SG1~DQ_BL_SGk and the second units of second data bits EB BL_SG1~EB_BL_SGk respectively to generate test data TD_SG1, TD_SG2, . . . , TD_SGk.

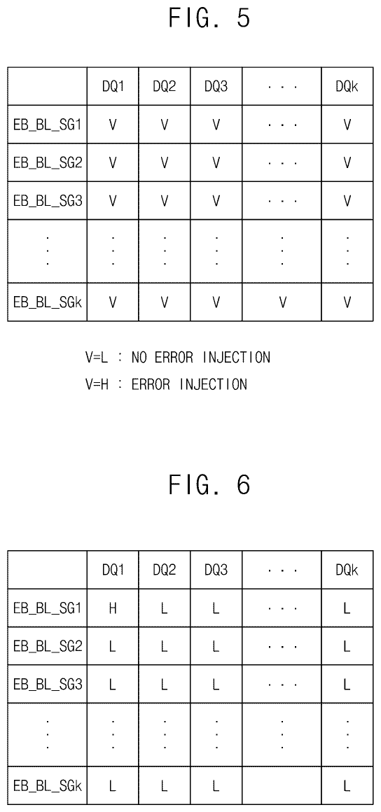

FIG. 5 illustrates second data bits that may be stored in the error injection register set in FIG. 4.

Referring to FIG. 5, second data bits V having a first logic level as a default logic level may be stored in the error injection registers 141~14k in the error injection register set 140. The register write circuit 150 may change at least one of the second data bits V to a second logic level such that the test data TD_SG1, TD_SG2, . . . , TD_SGk representing various error patterns may be provided to the semiconductor memory device 200.

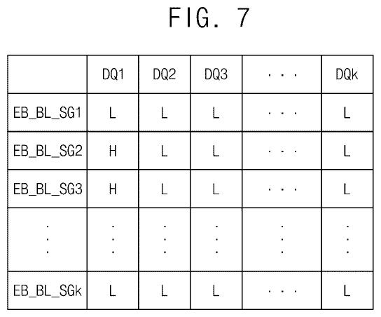

FIGS. 6 and 7 illustrate various error patterns that the error injection register set may represent according to example embodiments.

FIG. 6 illustrates an error pattern that indicates a single bit error.

Referring to FIG. 6, only one of the second data bits EB_BL_SG1~EB_BL_SGk has a logic high level. Therefore, it is noted that the error pattern of FIG. 6 represents a single bit error.

FIG. 7 illustrates an error pattern that indicates a double bit error.

Referring to FIG. 7, two of the second data bits EB_BL_SG1~EB_BL_SGk have a logic high level. Therefore, it is noted that the error pattern of FIG. 7 represents a double bit error.

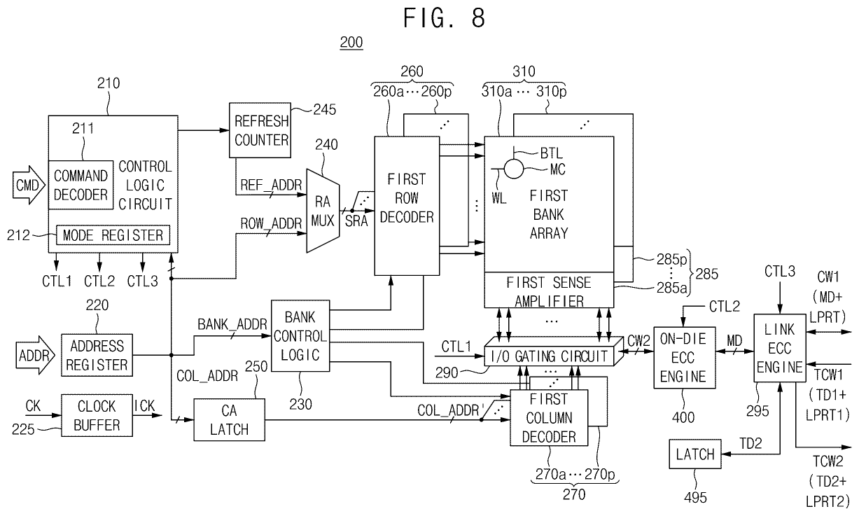

FIG. 8 is a block diagram illustrating an example of the semiconductor memory device in the memory system of FIG. 1 according to example embodiments.

Referring to FIG. 8, the semiconductor memory device 200 may include the control logic circuit 210, an address register 220, a bank control logic 230, a refresh counter 245, a row address multiplexer 240, a column address latch 250, a row decoder 260, a column decoder 270, the memory cell array 310, a sense amplifier group 285, an I/O gating circuit 290, the on-die engine 400, a clock buffer 225, the link ECC engine 295 and the latch 495.

The memory cell array 310 may include first through sixteenth bank arrays 310a~310p. The row decoder 260 may include first through sixteenth row decoders 260a260p respectively coupled to the first through sixteenth bank arrays 310a~310p, the column decoder 270 may include first through sixteenth column decoders 270a~270p respectively coupled to the first through sixteenth bank arrays 310a~310p, and the sense amplifier group 285 may include first through sixteenth sense amplifiers 285a~285p respectively coupled to the first through sixteenth bank arrays 310a~310p.

The first through sixteenth bank arrays 310a~310p, the first through sixteenth row decoders 260a260p, the first through sixteenth column decoders 270a~270p and first through sixteenth sense amplifiers 285a~285p may form first through sixteenth banks. Each of the first through sixteenth bank arrays 310a~310p may include a plurality of memory cells MC formed at intersections of a plurality of word-lines WL and a plurality of bit-lines BTL.

The address register 220 may receive the address ADDR including a bank address BANK_ADDR, a row address ROW_ADDR and a column address COL_ADDR from the memory controller 100. The address register 220 may provide the received bank address BANK_ADDR to the bank control logic 230, may provide the received row address ROW_ADDR to the row address multiplexer 240, and may provide the received column address COL_ADDR to the column address latch 250.

The bank control logic 230 may generate bank control signals in response to the bank address BANK_ADDR. One of the first through sixteenth row decoders 260a~260p corresponding to the bank address BANK_ADDR may be activated in response to the bank control signals, and one of the first through sixteenth column decoders 270a~270p corresponding to the bank address BANK_ADDR may be activated in response to the bank control signals.

The row address multiplexer 240 may receive the row address ROW_ADDR from the address register 220, and may receive a refresh row address REF_ADDR from the refresh counter 245. The row address multiplexer 240 may selectively output the row address ROW_ADDR or the refresh row address REF_ADDR as a row address SRA. The row address SRA that is output from the row address multiplexer 240 may be applied to the first through sixteenth row decoders 260a~260p.

The refresh counter 245 may sequentially increase or decrease the refresh row address REF_ADDR under control of the control logic circuit 210.

The activated one of the first through sixteenth row decoders 260a~260p, by the bank control logic 230, may decode the row address SRA that is output from the row address multiplexer 240, and may activate a word-line corresponding to the row address SRA. For example, the activated row decoder may apply a word-line driving voltage to the word-line corresponding to the row address SRA.

The column address latch 250 may receive the column address COL_ADDR from the address register 220, and may temporarily store the received column address COL_ADDR. In some example embodiments, in a burst mode, the column address latch 250 may generate column address COL_ADDR′ that increment from the received column address COL_ADDR. The column address latch 250 may apply the temporarily stored or generated column address COL_ADDR′ to the first through sixteenth column decoders 270a~270p.

The activated one of the first through sixteenth column decoders 270a~270p, by the bank control logic 230, may activate a sense amplifier corresponding to the bank address BANK_ADDR and the column address COL_ADDR through the I/O gating circuit 290.

The I/O gating circuit 290 may include a circuitry for gating input/output data, and may further include input data mask logic, read data latches for storing data that is output from the first through sixteenth bank arrays 310a~310p, and write drivers for writing data to the first through sixteenth bank arrays 310a~310p.

In a read operation of the normal mode, codeword CW2 read from a selected one bank array of the first through sixteenth bank arrays 310a~310p may be sensed by a sense amplifier coupled to the selected one bank array from which the data is to be read, and is stored in the read data latches. The codeword CW2 stored in the read data latches may be provided to the link ECC engine 295 as the main data MD after ECC decoding is performed on the codeword CW2 by the on-die ECC engine 400. The link ECC engine 295 may generate the link parity data LPRT by performing an ECC encoding operation on the main data MD and transmit a codeword CW1 including the main data MD and the link parity data LPRT to the memory controller 100.

In a write operation of the normal mode, the link ECC engine 295 may receive the codeword CW1 including the link parity data LPRT and the main data MD to be written in a selected one bank array of the first through sixteenth bank arrays 310a~310p from the memory controller 100. The link ECC engine 295 may provide the main data MD to the on-die ECC engine 400 by performing an ECC decoding operation on the main data MD based on the link parity data LPRT to correct at least one error bit occurring during the codeword CW1 is being transmitted. The on-die ECC engine 400 may perform an ECC encoding operation on the main data MD to generate parity bits (or parity data), and the on-die ECC engine 400 may provide the codeword CW2 including main data MD and the parity bits to the I/O gating circuit 290. The I/O gating circuit 290 may write the codeword CW2 in a sub-page in the selected one bank array through the write drivers.

In a write operation of the test mode, the link ECC engine 295 may receive a first test codeword TCW1 including a first link parity data LPRT1 and a first test data TD1 that selectively includes at least one error bit from the memory controller 100, may generate a second test data TD2 by performing an ECC decoding operation (a first ECC decoding operation) on the first test data TD1 based on the first link parity data LPRT1 to correct at least one error bit in the first test data TD1, and may store the second test data TD2 in the latch 495.

In a read operation of the test mode, the link ECC engine 295 may receive the second test data TD2 stored in the latch 495, may generate a second link parity data LPRT2 by performing an ECC encoding operation on the second test data TD2 and may transmit a second test codeword TCW2 including the second test data TD2 and the second link parity data LPRT2 to the memory controller 100.

The memory controller 100 may determine (e.g., test) whether the link ECC engine 295 operates normally by comparing each of the second test data TD2 and the second link parity data LPRT2 with respective one of the expected test data and the expected link parity data.

The control logic circuit 210 may set the on-die ECC engine 400 and the link ECC engine 295 to the test mode in response to a first mode register set command from the memory controller 100, may cut off connection between the on-die ECC engine 400 and the memory cell array 310 by disabling the on-die ECC engine 400, and may test the link ECC engine 295 based on the first test data TDI including various error patterns.

The on-die ECC engine 400, in the normal mode, may perform an ECC encoding operation on the main data MD and may perform an ECC decoding operation on the codeword CW2 based on a second control signal CTL2 from the control logic circuit 210.

The clock buffer 225 may receive the clock signal CK, may generate an internal clock signal ICK by buffering the clock signal CK, and may provide the internal clock signal ICK to circuit components processing the command CMD and the address ADDR.

The control logic circuit 210 may control operations of the semiconductor memory device 200. For example, the control logic circuit 210 may generate control signals for the semiconductor memory device 200 in order to perform a write operation, a read operation, a refresh operation or operations in the test mode. The control logic circuit 210 may include a command decoder 211 that decodes the command CMD received from the memory controller 100 and a mode register 212 that sets an operation mode of the semiconductor memory device 200.

For example, the command decoder 211 may generate the control signals corresponding to the command CMD by decoding a write enable signal, a row address strobe signal, a column address strobe signal, a chip select signal, etc. The control logic circuit 210 may provide a first control signal CTL1 to the I/O gating circuit, the second control signal CTL2 to control the on-die ECC engine 400 and a third control signal CTL3 to control the link ECC engine 295.

The mode register 212 may store a plurality of operation codes and the operations in the test mode may be set based on a portion of the plurality of operation codes.

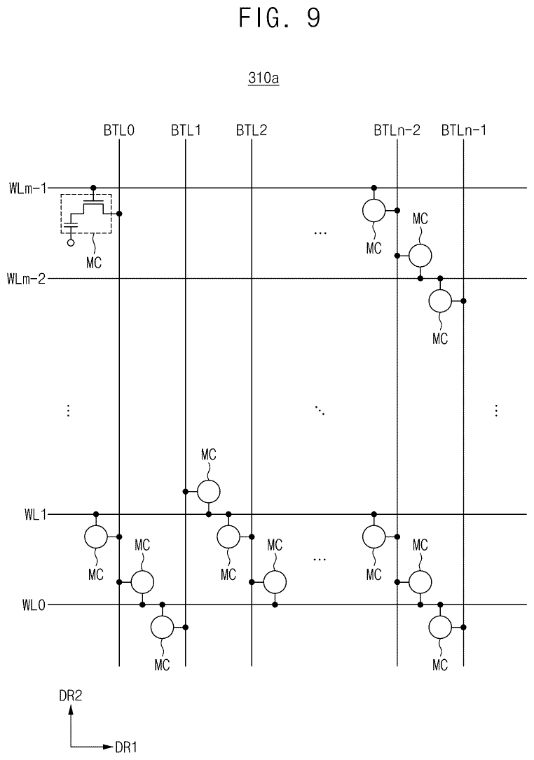

FIG. 9 illustrates an example of the first bank array in the semiconductor memory device of FIG. 8 according to example embodiments.

Referring to FIG. 9, the first bank array 310a may include a plurality of word-lines WL0~WLm−1 (m is a natural number greater than two), a plurality of bit-lines BTL0~BTLn−1 (n is a natural number greater than two), and a plurality of memory cells MCs disposed at intersections between the word-lines WL0~WLm−1 and the bit-lines BTL0~BTLn−1. Each of the memory cells MCs includes a cell transistor coupled to each of the word-lines WL0~WLm−1 and each of the bit-lines BTL0~BTLn−1 and a cell capacitor coupled to the cell transistor.

Each of the word-lines WL0~WLm−1 extends in a first direction DR1 and each of the bit-lines BTL1~BTLn−1 extends in a second direction DR2 perpendicular to the first direction DR1.

In addition, the memory cells MCs may have different arrangement depending on whether the memory cells MCs are coupled to an even word-line (for example, WL0) or an odd word-line (for example, WL1). That is, a bit-line coupled to adjacent memory cells may be different depending on whether a word-line selected by an access address is an even word-line or an odd word-line. Each of the memory cells MCs may include an access (cell) transistor coupled to one of the word-lines WL0~WLm−1 and one of the bit-lines BTL0~BTLn−1 and a storage (cell) capacitor coupled to the cell transistor. That is, each of the memory cells MCs may have a DRAM cell structure.

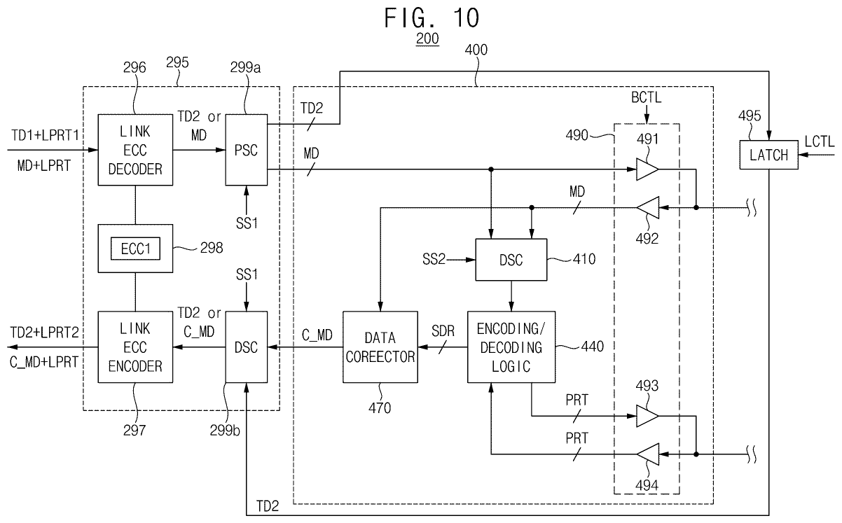

FIG. 10 illustrates a portion of the semiconductor memory device of FIG. 8.

In FIG. 10, the link ECC engine 295, the on-die ECC engine 400 and the latch 495 of the semiconductor memory device 200 are illustrated.

Referring to FIG. 10, the link ECC engine 295 may include a link ECC decoder 296, a link ECC encoder 297, a memory 298, a path selection circuit PSC 299a and a data selection circuit DSC 299b.

The on-die ECC engine 400 may include a data selection circuit 410, an encoding/decoding logic 440, a data corrector 470 and a buffer circuit 490.

The buffer circuit 490 may include a plurality of buffers 491, 492, 493 and 494. The plurality of buffers 491, 492, 493 and 494 may be controlled based on a buffer control signal BCTL.

The link ECC decoder 296, in the test mode, may receive the first link parity data LPRT1 and the first test data TD1 that selectively includes at least one error bit, may generate the second test data TD2 by performing a first ECC decoding operation on the first test data TD1 based on the first link parity data LPRT1 using a first ECC ECC1 stored in the memory 298 and by correcting at least one error bit in the first test data TD1. The link ECC decoder 296 may provide the second test data TD2 to the path selection circuit 299a. The first ECC ECC1 may be a single error correction/double error detection (SECDED) code.

The link ECC decoder 296 may correct x error bit in the first test data TD1 and detect (x+1) error bits in the first test data TD1, and x may be a natural number.

The link ECC decoder 296, in the normal mode, may receive the main data MD and the link parity data LPRT, may recover the main data MD by performing an ECC decoding operation on the main data MD based on the link parity data LPRT using the first ECC ECC1 stored in the memory 298 and by correcting at least one error bit in the main data MD. The link ECC decoder 296 may provide the main data MD to the path selection circuit 299a.

The path selection circuit 299a, based on a first selection signal SS1, may provide the second test data TD2 to the latch 495 in the test mode and may provide the main data MD to the data selection circuit 410 and the buffer 491 in the on-die ECC engine 400, in the normal mode.

The data selection circuit 410, in the normal mode, may receive the main data MD from the buffer 492 and may provide the main data MD to the encoding/decoding logic 440 based on a second selection signal SS2.

The encoding/decoding logic 440, in the write operation of the normal mode, may receive the main data MD from the data selection circuit 410, may generate a parity data PRT by performing on an ECC encoding operation on the main data MD and may provide the parity data PRT to the memory cell array 310 through the buffer 493. The encoding/decoding logic 440, in the read operation of the normal mode, may receive the main data MD from the data selection circuit 410, may receive the parity data PRT from the buffer 494, may generate a syndrome SDR by performing on an ECC decoding operation on the main data MD based on the parity data PRT and may provide the syndrome SDR to the data corrector 470.

The data corrector 470, in the read operation of the normal mode, may receive the main data MD, may generate a corrected main data C_MD by correcting an error bit in the main data MD based on the syndrome SDR and may provide the corrected main data C_MD to the data selection circuit 299b.

The latch 495 may provide the second test data TD2 to the data selection circuit 299b based on a latch control signal LCTL in the read operation of the test mode.

The data selection circuit 299b, based on the first selection signal SS1, may provide the second test data TD2 to the link ECC encoder 297 in the test mode, and may provide the corrected main data C_MD to the link ECC encoder 297 in the normal mode.

The link ECC encoder 297, in the test mode, may generate the second link parity data LPRT2 by performing an ECC encoding operation on the second test data TD2 based on the first ECC ECC1, and may transmit the second test data TD2 and the second link parity data LPRT2 to the memory controller 100.

The link ECC encoder 297, in the normal mode, may generate the link parity data LPRT by performing an ECC encoding operation on the corrected main data C_MD based on the first ECC ECC1, and may transmit the corrected main data C_MD and the link parity data LPRT to the memory controller 100.

In FIG. 10, the first selection SS1 may be included in the third control signal CTL3 in FIG. 8 and the second selection signal SS2 and the buffer control signal BCTL may be included in the second control signal CTL2 in FIG. 8.

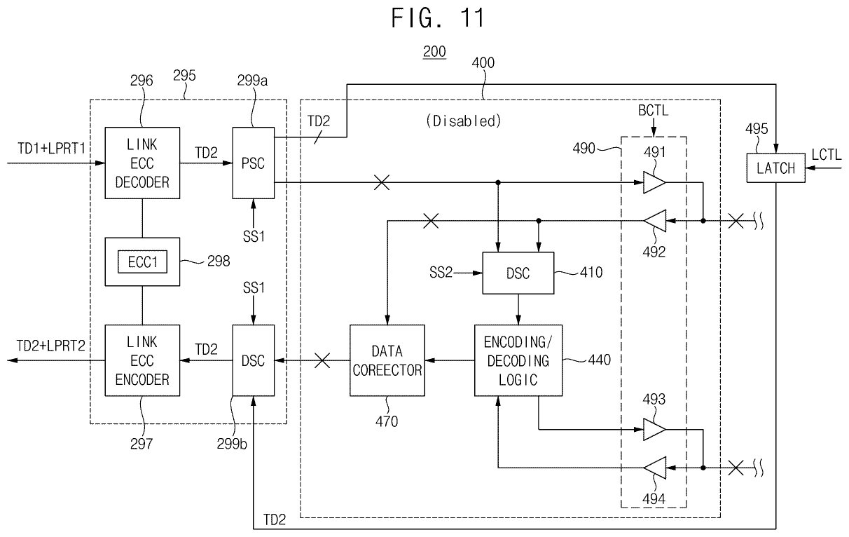

FIG. 11 illustrates the semiconductor memory device of FIG. 10 in the test mode.

In FIG. 11, descriptions repeated with FIG. 10 will be omitted for convenience of explanation.

The link ECC decoder 296, in the test mode, may receive the first link parity data LPRT1 and the first test data TD1 that selectively includes at least one error bit, may generate the second test data TD2 by performing a first ECC decoding operation on the first test data TD1 based on the first link parity data LPRT1 using a first ECC ECC1 stored in the memory 298 and by correcting at least one error bit in the first test data TD1. The link ECC decoder 296 may store the second test data TD2 in the latch 495 through the path selection circuit 299a.

The latch 495 may provide the second test data TD2 to the data selection circuit 299b based on the latch control signal LCTL in the read operation of the test mode. The data selection circuit 299b, based on the first selection signal SS1, may provide the second test data TD2 to the link ECC encoder 297 in the test mode.

The link ECC encoder 297, in the test mode, may generate the second link parity data LPRT2 by performing an ECC encoding operation on the second test data TD2 based on the first ECC ECC1, and may transmit the second test data TD2 and the second link parity data LPRT2 to the memory controller 100.

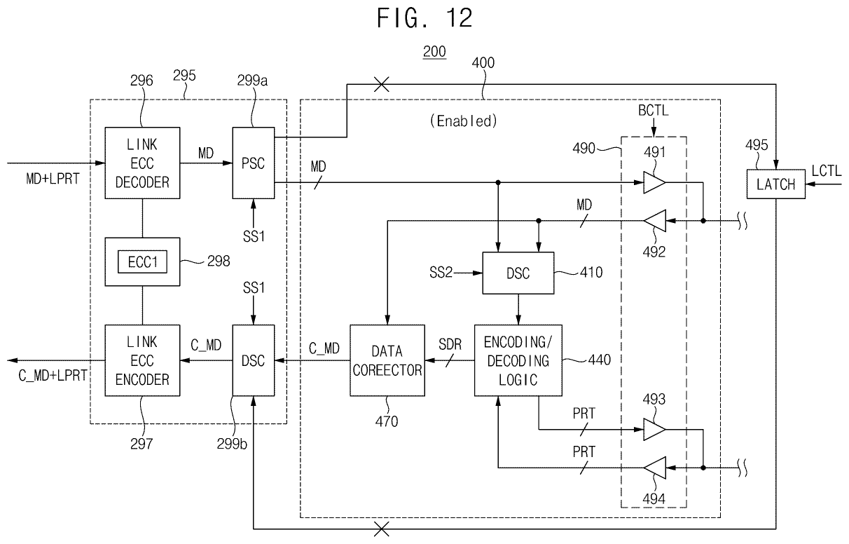

FIG. 12 illustrates the semiconductor memory device of FIG. 10 in the normal mode.

In FIG. 12, descriptions repeated with FIG. 10 will be omitted for convenience of explanation.

The link ECC decoder 296, in the normal mode, may receive the main data MD and the link parity data LPRT, may recover the main data MD by performing an ECC decoding operation on the main data MD based on the link parity data LPRT using the first ECC ECC1 stored in the memory 298 and by correcting at least one error bit in the main data MD. The link ECC decoder 296 may provide the main data MD to the on-die ECC engine 400 through the path selection circuit 299a.

The encoding/decoding logic 440, in the write operation of the normal mode, may receive the main data MD from the data selection circuit 410, may generate a parity data PRT by performing on an ECC encoding operation on the main data MD and may provide the parity data PRT to the memory cell array 310 through the buffer 493. The encoding/decoding logic 440, in the read operation of the normal mode, may receive the main data MD from the data selection circuit 410, may receive the parity data PRT from the buffer 494, may generate a syndrome SDR by performing on an ECC decoding operation on the main data MD based on the parity data PRT and may provide the syndrome SDR to the data corrector 470.

The data corrector 470, in the read operation of the normal mode, may receive the main data MD, may generate a corrected main data C_MD by correcting an error bit in the main data MD based on the syndrome SDR and may provide the corrected main data C_MD to the data selection circuit 299b.

The link ECC encoder 297, in the normal mode, may generate the link parity data LPRT by performing an ECC encoding (a second ECC encoding) on the corrected main data C_MD based on the first ECC ECC1, and may transmit the corrected main data C_MD and the link parity data LPRT to the memory controller 100.

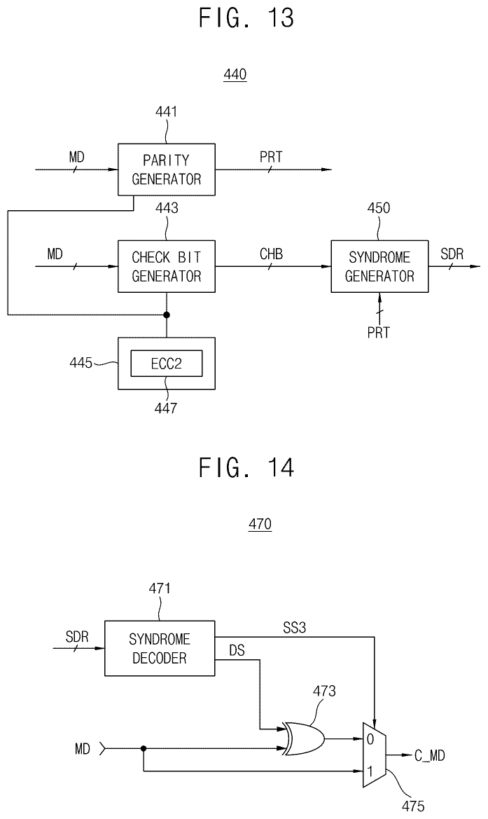

FIG. 13 illustrates an example of the encoding/decoding logic in the on-die ECC engine of FIG. 10 according to example embodiments.

Referring to FIG. 13, the encoding/decoding logic 440 may include a parity generator 441, a check bit generator 443, a syndrome generator 450 and a memory 445. The memory may store a second ECC (ECC2) 447.

The parity generator 441 may be connected to the memory 445 and may generate the parity data PRT based on the main data MD using an array of exclusive OR gates.

The check bit generator 443 may be connected to the memory 445 and may generate check bits CHB based on the main data MD in the read operation of the normal mode. The syndrome generator 450 may generate the syndrome data SDR based on the check bits CHB based on the main data MD and the parity data PRT from the buffer 494 in the read operation of the normal mode. The syndrome generator 450 may generate the syndrome SDR based on whether each of the check bits CHB is equal to a corresponding one of bits of the parity data PRT.

The syndrome SDR may include a plurality of syndrome bits and the plurality of syndrome bits may indicate whether each of the check bits CHB is equal to a corresponding one of bits of the parity data PRT. Therefore, the syndrome SDR may indicate a position of the error bit and a number of the error bit(s).

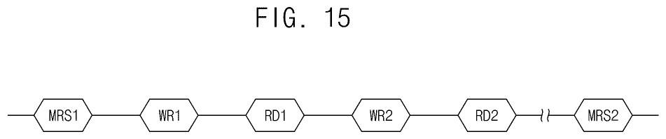

FIG. 14 illustrates an example of the data corrector in the on-die ECC engine of FIG. 10 according to example embodiments.

Referring to FIG. 14, the data corrector 470 may include a syndrome decoder 471, a bit inverter 473 and a selection circuit 475 which is implemented by a multiplexer.

The syndrome decoder 471 may decode the syndrome SDR to generate a decoding signal DS and a third selection signal SS3. The decoding signal DS may indicate a position of the at least one error and the third selection signal SS3 may have a logic level depending on a number of the at least one error bit. The bit inverter 473 may invert the at least one error bit in response to the decoding signal DS. The selection circuit 475 may select one of the main data MD and an output of the bit inverter 473 to provide the corrected main data C_MD in response to the third selection signal SS3 in the normal mode.

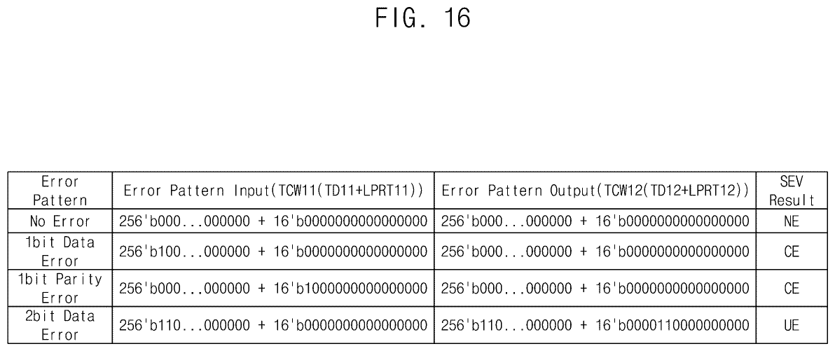

FIG. 15 illustrates a command sequence that the semiconductor memory device receives in the test mode according to example embodiments.

Referring to FIGS. 1, 10, 11 and 15, the memory controller 100 applies a first mode register set command MRS1 to the semiconductor memory device 200 such that the semiconductor memory device 200 enters into the test mode.

The memory controller 100 applies a first write command WR1, the first test data TD1 and the first link parity data LPRT1 to the semiconductor memory device 200. The link ECC engine 295 performs an ECC decoding operation on the first test data TD1 to generate the second test data TD2 and stores the second test data TD2 in the latch 495.

The memory controller 100 applies a first read command RD1 to the semiconductor memory device 200. The link ECC engine 295 performs an ECC encoding operation on the second test data TD2 stored in the latch 495 to generate the second link parity data LPRT2. The link ECC engine 295 transmits the second test data TD2 and the second link parity data LPRT2 to the memory controller 100.

The memory controller 100 applies a second write command WR2, a third test data and a third link parity data to the semiconductor memory device 200. The link ECC engine 295 performs an ECC decoding operation on the third test data to generate a fourth test data and stores the fourth test data in the latch 495.

The memory controller 100 applies a second read command RD2 to the semiconductor memory device 200. The link ECC engine 295 performs an ECC encoding operation on the fourth test data stored in the latch 495 to generate a fourth link parity data and transmits the fourth test data and the fourth link parity data to the memory controller 100.

The above-mentioned process is repeated on various test data while in the test mode. To exit the test mode, the memory controller 100 applies a second mode register set command MRS2 to the semiconductor memory device 200 and the semiconductor memory device 200 exits from the test mode in response to the second mode register set command MRS2.

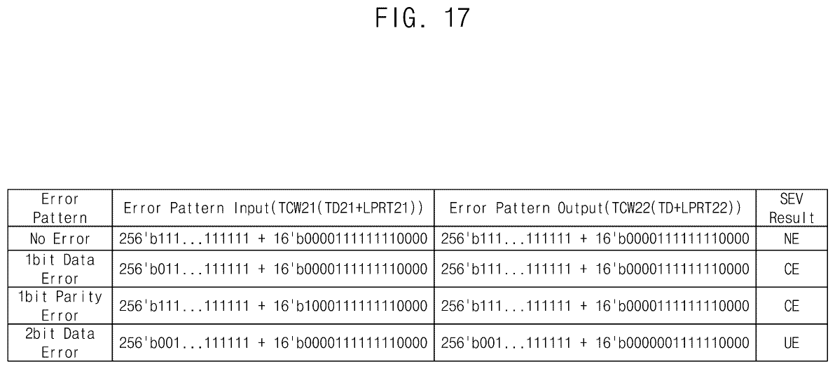

FIG. 16 illustrates data input to/output from the link ECC engine of FIG. 10 in the test mode according to example embodiments.

In FIG. 16, Error Pattern Input may correspond to a first test codeword TCW11 including a first test data TD11 and a first link parity data LPRT11 which are input to the link ECC engine 295, Error Pattern Output may correspond to a second test codeword TCW12 including a second test data TD12 and a second link parity data LPRT12 which are output from the link ECC engine 295, and SEV Result may correspond to the severity signal SEV in FIG. 2. A logic high level in the Error Pattern Input and the Error Pattern Output may indicate an error bit in FIG. 16.

In addition, in FIG. 16, each of the Error Pattern Input and the Error Pattern Output may include 265 data bits and 16 link parity bits.

Referring to FIG. 16, when the Error Pattern Input includes no error bit, the Error Pattern Output includes no error bit, the decision logic 185 in FIG. 2 may provide the CPU 110 with the severity signal SEV indicating that no error bit NE is detected and the CPU 110 may determine that the link ECC engine 295 operates normally based on the severity signal SEV.

When the Error Pattern Input includes an error bit (correctable error bit by the link ECC engine 295), the link ECC engine 295 may correct the error bit and may transmit the Error Pattern Output including no error bit to the memory controller 100. The decision logic 185 in FIG. 2 may provide the CPU 110 with the severity signal SEV indicating that a correctable error bit CE is corrected and the CPU 110 may determine that the link ECC engine 295 operates normally based on the severity signal SEV. When the link ECC engine 295 operates abnormally, the Error Pattern Output may include an error bit, and the decision logic 185 in FIG. 2 may provide the CPU 110 with the severity signal SEV indicating that an error bit is not corrected. The CPU 110 may determine that the link ECC engine 295 operates abnormally based on the severity signal SEV.

For example, when the data bits include an error bit and the Error Pattern Output includes an error bit, the CPU 110 may determine that the link ECC decoder 296 operates abnormally. For example, when the first link parity data LPRT11 include an error bit and the Error Pattern Output includes an error bit, the CPU 110 may determine that the link ECC encoder 297 operates abnormally.

When the Error Pattern Input includes two error bits (uncorrectable error bits by the link ECC engine 295), the link ECC engine 295 may generate the second test data TD12 by maintaining the first test data TD11 and may store the second test data TD12 in the latch 495. The link ECC encoder 297 may generate the second link parity data LPRT12 indicating that two error bits are detected by performing the ECC encoding operation on the second test data TD12 including two error bits, and may transmit the Error Pattern Output including the second test data TD12 and the second link parity data LPRT12 to the memory controller 100. The decision logic 185 may provide the CPU 110 with the severity signal SEV indicating that uncorrectable errors UE are detected by comparing each of the second test data TD12 and the second link parity data LPRT12 with respective one of the expected test data ETD and the expected link parity data ELPRT. The CPU 110 may determine that the link ECC engine 295 operates abnormally based on the severity signal SEV indicating that the uncorrectable errors UE are detected.

For example, when the second test data TD12 differs from the expected test data ETD, the CPU 110 may determine that the link ECC decoder 296 operates abnormally based on the severity signal SEV. For example, when the second link parity data LPRT12 differs from the expected link parity data ELPRT, the CPU 110 may determine that the link ECC encoder 297 operates abnormally based on the severity signal SEV.

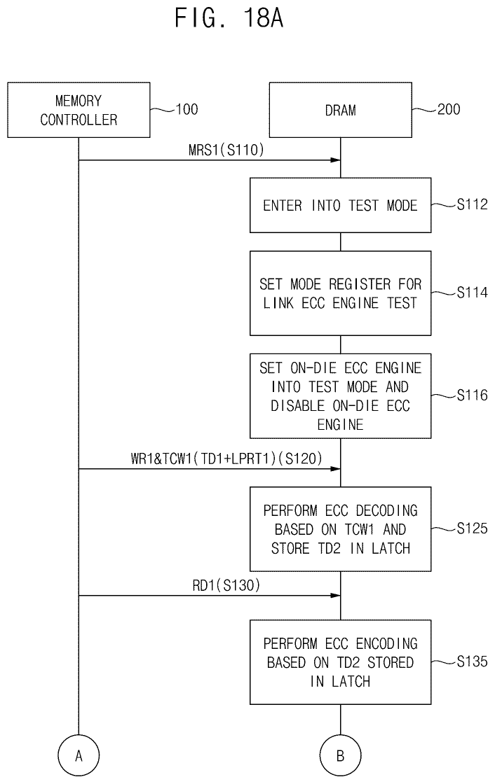

FIG. 17 illustrates data input to/output from the link ECC engine of FIG. 10 in the test mode according to example embodiments.

In FIG. 17, Error Pattern Input may correspond to a first test codeword TCW21 including a first test data TD21 and a first link parity data LPRT21 which are input to the link ECC engine 295, Error Pattern Output may correspond to a second test codeword TCW22 including a second test data TD22 and a second link parity data LPRT22 which are output from the link ECC engine 295, and SEV Result may correspond to the severity signal SEV in FIG. 2. A logic low level in the Error Pattern Input and the Error Pattern Output may indicate an error bit in FIG. 17.

In addition, in FIG. 17, each of the Error Pattern Input and the Error Pattern Output may include 265 data bits and 16 link parity bits.

Referring to FIG. 17, when the Error Pattern Input includes no error bit, and the Error Pattern Output includes no error bit, the decision logic 185 in FIG. 2 may provide the CPU 110 with the severity signal SEV indicating that no error bit NE is detected and the CPU 110 may determine that the link ECC engine 295 operates normally based on the severity signal SEV.

When the Error Pattern Input includes an error bit (correctable error bit by the link ECC engine 295), the link ECC engine 295 may correct the error bit and may transmit the Error Pattern Output including no error bit to the memory controller 100. The decision logic 185 in FIG. 2 may provide the CPU 110 with the severity signal SEV indicating that a correctable error bit CE is corrected and the CPU 110 may determine that the link ECC engine 295 operates normally based on the severity signal SEV. When the link ECC engine 295 operates abnormally, the Error Pattern Output may include an error bit, and the decision logic 185 in FIG. 2 may provide the CPU 110 with the severity signal SEV indicating that an error bit is not corrected. The CPU 110 may determine that the link ECC engine 295 operates abnormally based on the severity signal SEV.

For example, when the data bits include an error bit and the Error Pattern Output includes an error bit, the CPU 110 may determine that the link ECC decoder 296 operates abnormally. For example, when the first link parity data LPRT11 include an error bit and the Error Pattern Output includes an error bit, the CPU 110 may determine that the link ECC encoder 297 operates abnormally.

When the Error Pattern Input includes two error bits (uncorrectable error bits by the link ECC engine 295), the link ECC engine 295 may generate the second test data TD22 by maintaining the first test data TD21 and may store the second test data TD22 in the latch 495. The link ECC encoder 297 may generate the second link parity data LPRT22 indicating that two error bits are detected by performing the ECC encoding operation on the second test data TD22 including two error bits, and may transmit the Error Pattern Output including the second test data TD22 and the second link parity data LPRT22 to the memory controller 100. The decision logic 185 may provide the CPU 110 with the severity signal SEV indicating that uncorrectable errors UE are detected by comparing each of the second test data TD22 and the second link parity data LPRT22 with respective one of the expected test data ETD and the expected link parity data ELPRT. The CPU 110 may determine that the link ECC engine 295 operates abnormally based on the severity signal SEV indicating that the uncorrectable errors UE are detected.

For example, when the second test data TD22 differs from the expected test data ETD, the CPU 110 may determine that the link ECC decoder 296 operates abnormally based on the severity signal SEV. For example, when the second link parity data LPRT22 differs from the expected link parity data ELPRT, the CPU 110 may determine that the link ECC encoder 297 operates abnormally based on the severity signal SEV.

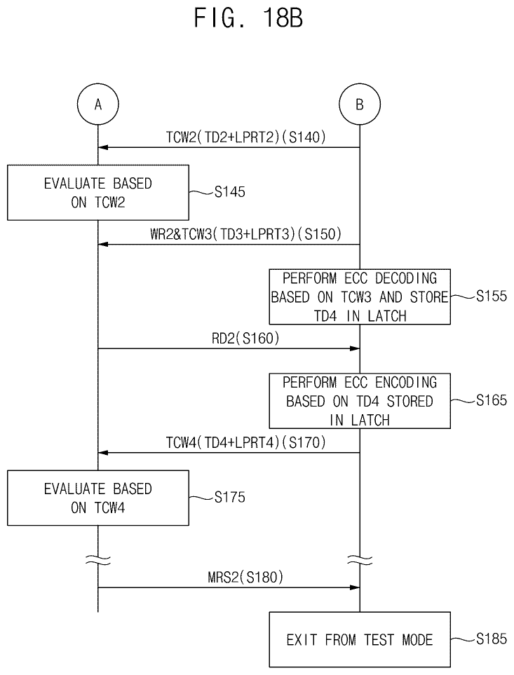

FIGS. 18A and 18B illustrate an example operation of the memory system of FIG. 1 according to example embodiments.

Referring to FIGS. 1, 8, 11, 15, 18A and 18B, the memory controller 100 applies a first mode register set command MRS1 to the semiconductor memory device 200 (operation S110) such that the semiconductor memory device 200 enters into the test mode (operation S112), and a plurality of operation codes of the mode register 212 are set to a mode for testing the link ECC engine 295 (operation S114). The control logic circuit 210 sets the on-die ECC engine 400 to a test mode and cuts off a connection between the on-die ECC engine 400 and the memory cell array 310 by disabling the on-die ECC engine 400 (operation S116).

The memory controller 100 applies a first write command WR1 and a first test codeword TCW1 including the first test data TD1 and the first link parity data LPRT1 to the semiconductor memory device 200 (operation S120), and the link ECC engine 295 performs an ECC decoding operation on the first test data TD1 to generate the second test data TD2 and stores the second test data TD2 in the latch 495 (operation S125).

The memory controller 100 applies a first read command RD1 to the semiconductor memory device 200 (operation S130). The link ECC engine 295 performs an ECC encoding operation on the second test data TD2 stored in the latch 495 to generate the second link parity data LPRT2 (operation S135) and transmits a second test codeword TCW2 including the second test data TD2 and the second link parity data LPRT2 to the memory controller 100 (operation S140).

The memory controller 100 evaluates the link ECC engine 295 based on the second test data TD2 and the second link parity data LPRT2 (operation S145). The memory controller 100 applies a second write command WR2 and a test codeword TCW3 including a third test data TD3 and a third link parity data LPRT3 to the semiconductor memory device 200 (operation S150). The link ECC engine 295 performs an ECC decoding operation on the third test data TD3 to generate a fourth test data TD4 and stores the fourth test data TD4 in the latch 495 (operation S155).

The memory controller 100 applies a second read command RD2 to the semiconductor memory device 200 (operation S160). The link ECC engine 295 performs an ECC encoding operation on the fourth test data TD4 stored in the latch 495 to generate a fourth link parity data LPRT4 (operation S165). The link ECC engine 295 transmits a fourth test codeword TCW4 including the fourth test data TD4 and the fourth link parity data LPRT4 to the memory controller 100 (operation S170).

The memory controller 100 evaluates the link ECC engine 295 based on the fourth test data TD4 and the fourth link parity data LPRT4 (operation S175).

The above-mentioned process is repeated on various test data, the memory controller 100 applies a second mode register set command MRS2 to the semiconductor memory device 200 (operation S180) and the semiconductor memory device 200 exits from the test mode in response to the second mode register set command MRS2 (operation S185).

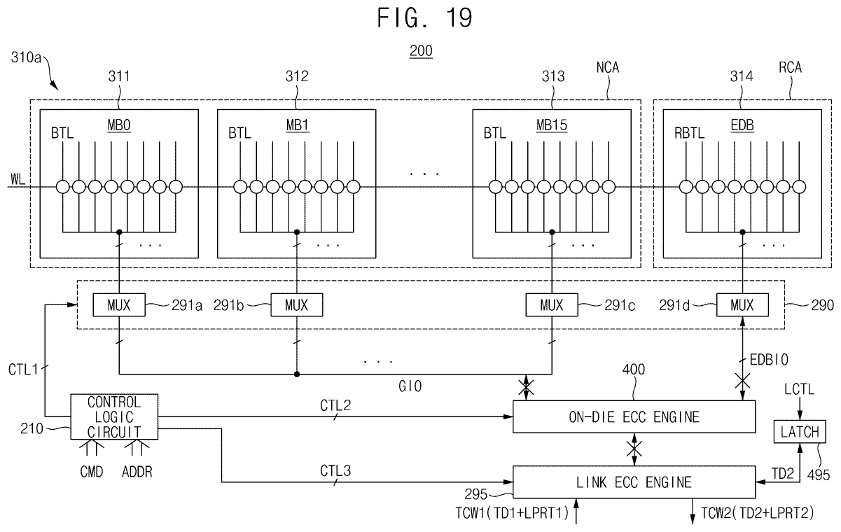

FIG. 19 illustrates a portion of the semiconductor memory device of FIG. 8 for explaining a test mode.

In FIG. 19, the control logic circuit 210, the first bank array 310a, the I/O gating circuit 290, the on-die ECC engine 400, the link ECC engine 295 and the latch 495 are illustrated.

Referring to FIG. 19, the first bank array 310a may include a normal cell region NCA and a redundancy cell region RCA.

The normal cell region NCA may include a plurality of first memory blocks MB0~MB15, e.g., 311, 312, . . . , 313 and the redundancy cell region RCA includes at least a second memory block 314. The first memory blocks 311, 312, . . . , 313 are memory blocks that determine or are used to determine a memory capacity of the semiconductor memory device 200. The second memory block 314 is for ECC and/or redundancy repair. The second memory block 314 may be referred to as an EDB block because the second memory block 314 for ECC and/or redundancy repair is used for ECC, data line repair and block repair to repair ‘failed’ cells generated in the first memory blocks 311, 312, . . . , 313. Each of the first memory blocks 311~313 includes memory cells coupled to a word-line WL and bit-lines BTL and the second memory block 314 includes memory cells coupled to word-line WL and redundancy bit-lines RBTL. The redundancy cell region RCA may be referred to as a parity cell region.

The I/O gating circuit 290 includes a plurality of switching circuits 291a, 291b, 291c and 291d respectively connected to the first memory blocks 311, 312, . . . , 313 and the second memory block 314.

The on-die ECC engine 400 may be connected to the switching circuits 291a, 291b, 291c and 291d through first data lines GIO and second data lines EDBIO. The control logic circuit 210 may receive the command CMD and the address ADDR and may decode the command CMD to generate the first control signal CTL1 for controlling the switching circuits 291a, 291b, 291c and 291d the second control signal CTL2 for controlling the on-die ECC engine 400 and the third control signal CTL3 for controlling the link ECC engine 295.

When the command CMD designates a test mode, the control logic circuit 210 may provide the second control signal CTL2 to the on-die ECC engine 400 to disable the on-die ECC engine 400 and to cut off a connection between the on-die ECC engine 400 and the first bank array 310a.

Based on a write command, the link ECC engine 295 may receive the first test codeword TCW1 including the first test data TD1 and the first link parity data LPRT1, may perform an ECC decoding operation on the first test data TD1 to generate the second test data TD2, and may store the second test data TD2 in the latch 495.

Based on a read command, the link ECC engine 295 may perform an ECC encoding operation on the second test data TD2 stored in the latch 495 to generate the second link parity data LPRT2, and may transmit the second test codeword TCW2 including the second test data TD2 and the second link parity data LPRT2 to the memory controller 100.

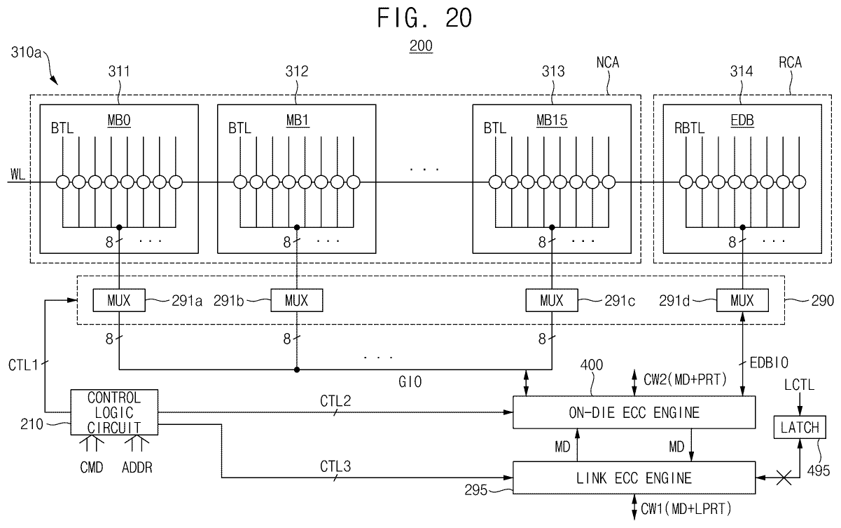

FIG. 20 illustrates a portion of the semiconductor memory device of FIG. 8 for explaining a normal mode.

In FIG. 20, descriptions repeated with FIG. 19 will be omitted.

Referring to FIG. 20, when the command CMD designates a write operation of the normal mode, the control logic circuit 210 may provide the second control signal CTL2 to the on-die ECC engine 400 and may provide the third control signal CTL3 to the link ECC engine 295.

Based on a write command, the link ECC engine 295 may receive a codeword CW1 including the main data MD and the link parity data LPRT, may perform an ECC decoding operation on the main data MD to correct an error bit in the main data and to recover the main data MD, and may provide the main data MD to the on-die ECC engine 400.

The on-die ECC engine 400, based on the second control signal CTL2, may perform an ECC encoding operation on the main data MD to generate a parity data PRT, and may provide the I/O gating circuit 290 with a codeword CW2 including the main data MD and the parity data PRT.

The control logic circuit 210 may provide the first control signal CTL1 to the I/O gating circuit 290 such that the codeword CW2 is to be stored in a sub-page of the target page in the first bank array 310a.

When the command CMD designates a read operation of the normal mode, the control logic circuit 210 may provide the first control signal CTL1 to the I/O gating circuit 290 such that the codeword CW2 stored in the sub-page of the target page in the first bank array 310a is provided to the on-die ECC engine 400.

The on-die ECC engine 400 may perform an ECC decoding operation on the main data MD and the parity data PRT in the codeword CW2, may correct an error bit in the codeword CW2 to output the (recovered) main data MD to the link ECC engine 295.

The link ECC engine 295 may perform an ECC encoding operation on the main data MD to generate the link parity data LPRT and may transmit the codeword CW1 including the main data MD and the link parity data LPRT to the memory controller 100.

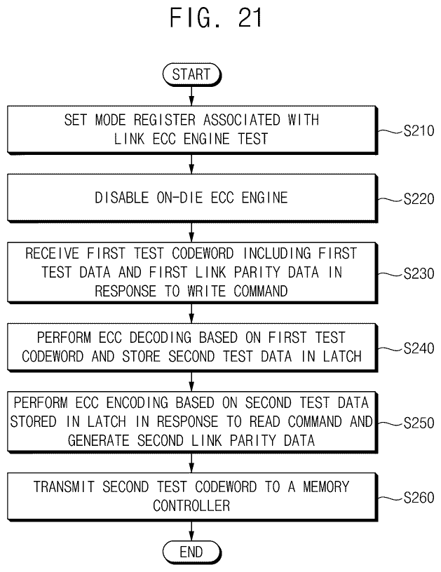

FIG. 21 is a flow chart illustrating a method of operating a semiconductor memory device according to example embodiments.

Referring to FIGS. 1 through 19 and 21, there is provided a method of operating a semiconductor memory device 200 that includes a memory cell array 310, an on-die ECC engine 400, a link ECC engine 295 and a control logic circuit 210.

According to the method, the mode register 212 in the control logic circuit 210 is set to a mode associated with testing the link ECC engine 295 in response to a first mode register set command from the memory controller (operation S210).

For testing the link ECC engine 295, the control logic circuit 210 disables the on-die ECC engine 400 (operation S220) and the link ECC engine 295 receives the first test codeword TCW1 including the first test data TD1 and the first link parity data LPRT1 from the memory controller 100 (operation S230).

The link ECC engine 295 performs an ECC decoding operation on the first test data TD1 based on the first link parity data LPRT1 to generate the second test data TD2, and may store the second test data TD2 in the latch 495 (operation S240).

Based on a read command from the memory controller 100, the link ECC engine 295 performs an ECC encoding operation on the second test data TD2 stored in the latch 495 to generate the second link parity data LPRT2 (operation S250), and transmits the second test codeword TCW2 including the second test data TD2 and the second link parity data LPRT2 to the memory controller 100 (operation S260).

The memory controller 100 determines (e.g., tests) whether the link ECC engine 295 operates normally based on the second test codeword TCW2.

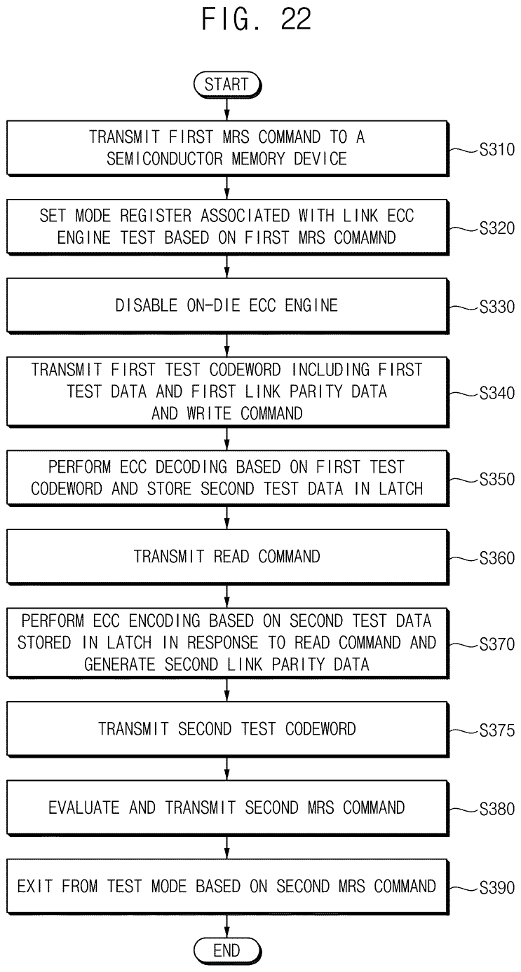

FIG. 22 is a flow chart illustrating a method of operating a memory system according to example embodiments.

Referring to FIGS. 1 through 19 and 22, there is provided a method of operating a memory system 20 including a semiconductor memory device 200 that includes a memory cell array 310, an on-die ECC engine 400, a link ECC engine and a control logic circuit 210 and a memory controller 100 that controls the semiconductor memory device 200.

According to the method, the memory controller 100 transmits a mode register set command to the semiconductor memory device 200 (operation S310).

The control logic circuit 210 sets the mode register 212 to a mode associated with testing the link ECC engine 295 in response to the first mode register set command (operation S320).

For testing the link ECC engine 295, the control logic circuit 210 disables the on-die ECC engine 400 (operation S330), and the memory controller 100 transmits a first test codeword TCW1 including a first test data TD1 and a first link parity data LPRT1 to the semiconductor memory device (operation S340).

The link ECC engine 295 performs an ECC decoding operation on the first test data TD1 based on the first link parity data LPRT1 to generate the second test data TD2 and may store the second test data TD2 in the latch 495 (operation S350).

The memory controller 100 transmits a read command to the semiconductor memory device 200 (operation S360). The link ECC engine 295, based on the read command, performs an ECC encoding operation on the second test data TD2 stored in the latch 495 to generate the second link parity data LPRT2 (operation S370) and transmits the second test codeword TCW2 including the second test data TD2 and the second link parity data LPRT2 to the memory controller 100 (operation S375).

The memory controller 100 determines (e.g., tests) whether the link ECC engine 295 operates normally based on the second test codeword TCW2 and transmits a second mode register set command to the semiconductor memory device 200 (operation S380).

The control logic circuit 210 exits from the test mode based on the second mode register set command (operation S390).

Therefore, according to the semiconductor memory device and the method of operating a semiconductor memory device, in the test mode, the control logic circuit may cut off a connection between the on-die ECC engine and the memory cell array, and the link ECC engine may generate a second test data by performing an ECC decoding operation on a first test data that selectively include an error bit based on a first link parity data, may store the second test data in the latch, may generate a second link parity data by performing an ECC encoding operation on the second test data and may transmit the second test data and the second link parity data to the memory controller. The memory controller may determine whether the link ECC engine operates normally based on the second test data and the second link parity dat. Therefore, the semiconductor memory device and the memory controller may test the link ECC engine with respect to various error patterns with blocking influence from the on-die ECC engine and the memory cell array and thus may enhance test coverage.

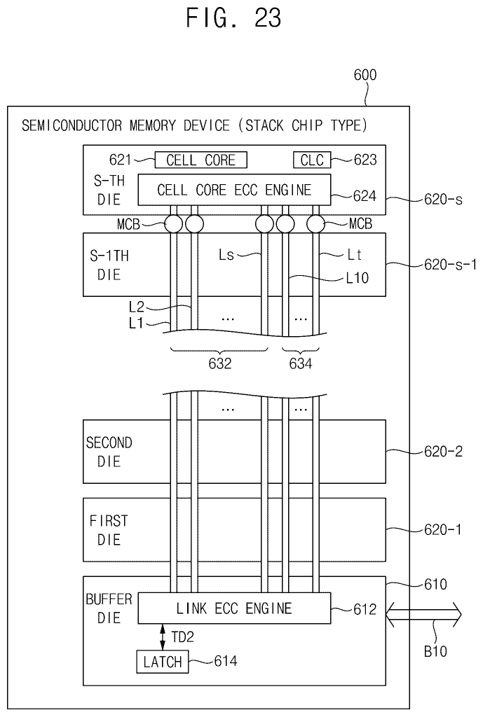

FIG. 23 is a block diagram illustrating a semiconductor memory device according to example embodiments.

Referring to FIG. 23, a semiconductor memory device 600 may include at least one buffer die 610 and a plurality of memory dies 620-1, 620-2, . . . , 620-s providing a soft error analyzing and correcting function in a stacked chip structure. Here, s is an integer greater than three.

The plurality of memory dies 620-1, 620-2, . . . , 620-s are stacked on the at least one buffer die 610 and conveys data through a plurality of through silicon via (TSV) lines.

Each of the memory dies 620-1, 620-2, . . . , 620-s may include a cell core 621 including a memory cell array, a cell core ECC engine 624 which generates transmission parity data (i.e., transmission parity data) based on transmission data to be sent to the at least one buffer die 610 and a control logic circuit (CLC) 623. The cell core ECC engine 624 may employ the on-die ECC engine 400 of FIG. 10.

The at least one buffer die 610 may include a link ECC engine 612 and a latch 614 The link ECC engine 612 may employ the link ECC engine 295 in FIG. 10. Therefore, the link ECC engine 612, in the test mode, may receive a first link parity data and a first test data that selectively includes an error bit, may generate a second test data TD2 by performing an ECC decoding operation on the first test data based on the first link parity data without transmitting the first test data to one of the memory dies 620-1, 620-2, . . . , 620-s, may store the second test data TD2 in the latch 614, may generate a second link parity data by performing on the second test data TD2 stored in the latch 614 and may transmit the second test data TD2 and the second link parity data to a memory controller.

The control logic circuit 623 may include a test mode register and the test mode register may determine a type of a background data, may determine whether a test parity data includes an error bit and may select a position of a parity bit including the error bit through a plurality of operation codes.

The semiconductor memory device 600 may be a stack chip type memory device or a stacked memory device which conveys data and control signals through the TSV lines. The TSV lines may be also called ‘through electrodes’.

A data TSV line group 632 which is formed at one memory die 620-s may include TSV lines L1, L2 to Lp, and a parity TSV line group 634 may include TSV lines L10 to Lq.

The TSV lines L1, L2 to Ls of the data TSV line group 632 and the parity TSV lines L10 to Lt of the parity TSV line group 634 may be connected to micro bumps MCB which are correspondingly formed among the memory dies 620-1, 620-2, . . . , 620-s.

Each of the memory dies 620-1, 620-2, . . . , 620-s may include DRAM cells each including at least one access transistor and one storage capacitor.

The semiconductor memory device 600 may have a three-dimensional (3D) chip structure or a 2.5D chip structure to communicate with the host through a data bus B10. The at least one buffer die 610 may be connected with the memory controller through the data bus B10.

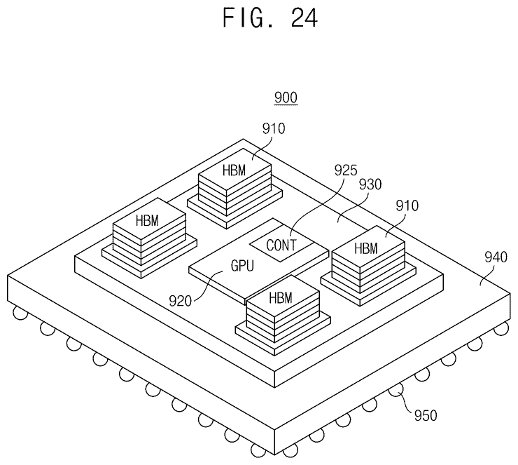

FIG. 24 is a diagram illustrating a semiconductor package including the stacked memory device, according to example embodiments.

Referring to FIG. 24, a semiconductor package 900 may include one or more stacked memory devices 910 and a graphic processing unit (GPU) 920. The GPU 920 may include a memory controller CONT 925.

The stacked memory devices 910 and the GPU 920 may be mounted on an interposer 930, and the interposer on which the stacked memory devices 910 and the GPU 920 are mounted may be mounted on a package substrate 940. The package substrate 940 may be mounted on solder balls 950. The memory controller 925 may employ the memory controller 100 in FIG. 1.

Each of the stacked memory devices 910 may be implemented in various forms, and may be a memory device in a high bandwidth memory (HBM) form in which a plurality of layers are stacked. Accordingly, each of the stacked memory devices 910 may include at least one buffer die and a plurality of memory dies. Each of the memory dies may include a memory cell array, an on-die ECC engine and a control logic circuit. The at least one buffer die may include a link ECC engine and a latch.

The plurality of stacked memory devices 910 may be mounted on the interposer 930, and the GPU 920 may communicate with the plurality of stacked memory devices 910. For example, each of the stacked memory devices 910 and the GPU 920 may include a physical region, and communication may be performed between the stacked memory devices 910 and the GPU 920 through the physical regions.

As mentioned above, according to example embodiments, in the semiconductor memory device, the control logic circuit in the test mode, may cut off a connection between the on-die ECC engine and the memory cell array, and the link ECC engine may generate a second test data by performing an ECC decoding operation on a first parity data that selectively include an error bit based on a first link parity data, may store the second test data in the latch, may generate a second link parity data by performing an ECC encoding operation on the second test data and may transmit the second test data and the second link parity data to the memory controller. The memory controller may determine whether the link ECC engine operates normally based on the second test data and the second link parity dat. Therefore, the semiconductor memory device may test the link ECC engine with respect to various error patterns with blocking influence from the on-die ECC engine and the memory cell array and thus may enhance test coverage.

Aspects of the present disclosure may be applied to systems using semiconductor memory devices that employ a link ECC engine, an on-die ECC engine and a plurality of volatile memory cells.

In some embodiments, each of the components represented by a block, such as those illustrated in FIGS. 1, 2, 4, 8, 10-14, 19, 20, 23 and 24 may be implemented as various numbers of hardware and/or firmware structures that execute respective functions described above, according to example embodiments. For example, at least one of these components may include various hardware components including a digital circuit, a programmable or non-programmable logic device or array, an application specific integrated circuit (ASIC), transistors, capacitors, logic gates, or other circuitry using use a direct circuit structure, such as a memory, a processor, a logic circuit, a look-up table, etc., that may execute the respective functions through controls of one or more microprocessors or other control apparatuses. Also, at least one of these components may further include or may be implemented by a processor such as a central processing unit (CPU) that performs the respective functions, a microprocessor, or the like. Functional aspects of example embodiments may be implemented in algorithms that execute on one or more processors. Furthermore, the components, elements, modules or units represented by a block or processing steps may employ any number of related art techniques for electronics configuration, signal processing and/or control, data processing and the like.

The foregoing is illustrative of example embodiments and is not to be construed as limiting thereof. Although a few example embodiments have been described, those skilled in the art will readily appreciate that many modifications are possible without materially departing from the novel teachings and advantages of the present disclosure. Accordingly, all such modifications are intended to be included within the scope of the present disclosure as defined in the claims.

What is claimed is:

1. A semiconductor memory device comprising:
a memory cell array comprising a plurality of memory cells coupled to a plurality of word-lines and a plurality of bit-lines;
an on-die error correction code (ECC) engine;
a link ECC engine;
a latch circuit; and
a control logic circuit configured to control the on-die ECC engine and the link ECC engine,
wherein the control logic circuit is further configured to, in response to a first mode register set command from an external device, set the on-die ECC engine and the link ECC engine to a test mode, and cut off connection between the on-die ECC engine and the memory cell array by disabling the on-die ECC engine, and
wherein the link ECC engine is configured to, in the test mode:
receive a write command, a first link parity data and a first test data that selectively comprises at least one error bit from the external device;
generate a second test data by performing an ECC decoding operation on the first test data based on the first link parity data and by correcting an error bit of the first test data; and
store the second test data in the latch circuit.

2. The semiconductor memory device of claim 1, wherein the first mode register set command corresponds to a test mode register set command.

3. The semiconductor memory device of claim 1, wherein the link ECC engine is further configured to correct x error bit and detect (x+1) error bits in the first test data, and x is a natural number.

4. The semiconductor memory device of claim 1, wherein the link ECC engine is further configured to, in the test mode:
generate a second link parity data by performing an ECC encoding operation on the second test data stored in the latch circuit in response to a read command from the external device; and
transmit the second test data and the second link parity data to the external device.

5. The semiconductor memory device of claim 1, wherein the link ECC engine comprises:
a link ECC decoder configured to, in the test mode, generate the second test data by performing the ECC decoding operation on the first test data based on a first ECC;
a link ECC encoder configured to, in the test mode, generate a second link parity data by performing an ECC encoding operation on the second test data based on the first ECC; and
a memory configured to store the first ECC, and
wherein the latch circuit is disposed at an outside of the on-die ECC engine and the link ECC engine.

6. The semiconductor memory device of claim 5, wherein the link ECC engine further include a path selection circuit, and
wherein the path selection circuit is configured to, based on a selection signal:
provide the second test data to the latch circuit in the test mode; and
provide the on-die ECC engine with a main data provided from the link ECC decoder.

7. The semiconductor memory device of claim 5, wherein the link ECC decoder is further configured to, in response to the first test data comprising no error bit, store the second test data in the latch circuit by maintaining the first test data, and
wherein the link ECC encoder is further configured to in response to the first test data comprising no error bit, generate the second link parity data indicating that the second test data includes no error bit, based on the second test data stored in the latch circuit.

8. The semiconductor memory device of claim 5, wherein the link ECC decoder is further configured to, in response to the first test data comprising a correctable error bit, store the second test data in the latch circuit by correcting the correctable error bit in the first test data, and
wherein the link ECC encoder is further configured to, in response to the first test data comprising the correctable error bit, generate the second link parity data indicating that the second test data includes no error bit, based on the second test data stored in the latch circuit.

9. The semiconductor memory device of claim 5, wherein the link ECC decoder is further configured to, in response to the first test data comprising uncorrectable error bits, store the second test data in the latch circuit by maintaining the first test data, and
wherein the link ECC encoder is further configured to, in response to the first test data comprising the uncorrectable error bits, generate the second link parity data indicating that the second test data includes the uncorrectable error bits, based on the second test data stored in the latch circuit.

10. The semiconductor memory device of claim 1, wherein, in a normal mode, the on-die ECC engine is configured to:
based on a write command, receive a main data from the link ECC engine, generate a parity data by performing an ECC encoding operation on the main data and store the main data and the parity data in a target page of the memory cell array; and
based on a read command, read the main data and the parity data from the target page, correct at least one error bit in the read main data by performing an ECC decoding operation on the read main data based on the read parity data to generate a corrected main data and provide the corrected main data to the link ECC engine.

11. The semiconductor memory device of claim 1, wherein the control logic circuit is further configured to exit from the test mode in response to a second mode register set command from the external device applied after a read command.

12. A memory system comprising:
a semiconductor memory device; and
a memory controller configured to control the semiconductor memory device,
wherein the semiconductor memory device comprises:
a memory cell array comprising a plurality of memory cells coupled to a plurality of word-lines and a plurality of bit-lines;
an on-die error correction code (ECC) engine;
a link ECC engine;
a latch circuit disposed at an outside of the on-die ECC engine and the link ECC engine; and
a control logic circuit configured to control the on-die ECC engine and the link ECC engine,
wherein the control logic circuit is further configured to, in response to a first mode register set command from the memory controller, set the on-die ECC engine and the link ECC engine to a test mode, and cut off a connection between the on-die ECC engine and the memory cell array by disabling the on-die ECC engine, and
wherein the link ECC engine is configured to, in the test mode:
receive a write command, a first link parity data and a first test data that selectively comprises at least one error bit from the memory controller;
generate a second test data by performing an ECC decoding operation on the first test data based on the first link parity data and by correcting an error bit of the first test data;
store the second test data in the latch circuit;
generate a second link parity data by performing an ECC encoding operation on the second test data stored in the latch circuit in response to a read command from the memory controller; and
transmit the second test data and the second link parity data to the memory controller.

13. The memory system of claim 12, wherein the memory controller is further configured to, in the test mode, test whether the link ECC engine operates normally by comparing each of the second test data and the second link parity data with respective one of an expected test data and an expected link parity data.

14. The memory system of claim 12, wherein the link ECC engine comprises:
a link ECC decoder configured to, in the test mode, generate the second test data by performing the ECC decoding operation on the first test data based on a first ECC code;
a link ECC encoder configured to, in the test mode, generate the second link parity data by performing an ECC encoding operation on the second test data based on the first ECC code; and
a memory configured to store the first ECC code.

15. The memory system of claim 14, wherein the memory controller is configured to:
determine whether the link ECC decoder operates normally by comparing the second test data with an expected test data; and
determine whether the link ECC encoder operates normally by comparing the second link parity data with an expected link parity data.

16. The memory system of claim 14, wherein the memory controller comprises:
a test data generator configured to generate the first test data, in the test mode;
a link parity generator configured to generate the first link parity data based on the first test data;
a decision logic circuit configured to generate a severity signal by comparing each of the second test data and the second link parity data with respective one of an expected test data and an expected link parity data, in the test mode; and
a central processing unit (CPU) configured to determine whether the link ECC engine operates normally based on the severity signal.

17. The memory system of claim 16, wherein the test data generator is further configured to generate the first test data comprising no error bit,
wherein the link ECC decoder is further configured to store the second test data in the latch circuit by maintaining the first test data,
wherein the link ECC encoder is further configured to generate the second link parity data based on the second test data stored in the latch circuit, and
wherein the decision logic circuit is further configured to generate the severity signal indicating that the link ECC encoder operates normally based on the second link parity data indicating that the second test data includes no error bit.

18. The memory system of claim 16, wherein the test data generator is further configured to generate the first test data comprising a correctable error bit,
wherein the link ECC decoder is further configured to store the second test data in the latch circuit by correcting the correctable error bit in the first test data,
wherein the link ECC encoder is further configured to generate the second link parity data based on the second test data stored in the latch circuit, and
wherein the decision logic circuit is further configured to generate the severity signal indicating that the link ECC encoder operates normally based on the second link parity data indicating that the second test data includes no error bit.

19. The memory system of claim 16, wherein the test data generator is further configured to generate the first test data comprising uncorrectable error bits,
wherein the link ECC decoder is further configured to store the second test data in the latch circuit by maintaining the first test data,
wherein the link ECC encoder is further configured to generate the second link parity data based on the second test data stored in the latch circuit, and
wherein the decision logic circuit is further configured to generate the severity signal indicating that the link ECC encoder operates normally based on the second link parity data indicating that the second test data includes the uncorrectable error bits.

20. A semiconductor memory device comprising:
a memory cell array comprising a plurality of memory cells coupled to a plurality of word-lines and a plurality of bit-lines;
an on-die error correction code (ECC) engine;
a link ECC engine;
a latch circuit disposed at an outside of the on-die ECC engine and the link ECC engine; and
a control logic circuit configured to control the on-die ECC engine and the link ECC engine,
wherein the control logic circuit is further configured to, in response to a mode register set command from an external device, set the on-die ECC engine and the link ECC engine to a test mode, and cut off a connection between the on-die ECC engine and the memory cell array by disabling the on-die ECC engine, and
wherein the link ECC engine, in the test mode, is configured to:
generate a link parity data by performing an ECC encoding operation on a test data stored in the latch circuit based on a read command from the external device; and
transmit the test data and the link parity data to the external device.
